(19) United States
(12) Patent Application Publication
(10) Pub. No.: US 2007/0285195 A1
(43) Pub. Date: Dec. 13, 2007

(54) Direct flux control system for magnetic structures

(76) Inventors: Thomas W. Nehl, Shelby Township, MI (US); Suresh Gopalakrishnan, Farmington Hills, MI (US); Fang Deng, Novi, MI (US)

Correspondence Address: Delphi Technologies, Inc., M/C 480-410-202, P.O. Box 5052, Troy, MI, 48007-5052, US

(21) Appl. No.: 11/451,953

(22) Filed: Jun. 13, 2006

(51) Int. Cl. H01F 1/00

(52) U.S. Cl. 335/209

(57) ABSTRACT

A method for controlling a magnetic structure including the steps of determining a flux associated with the magnetic structure and generating a control signal based, at least in part, upon the determined flux.

### BACKGROUND

The present application relates to systems and methods for controlling magnetic structures and, more particularly, to systems and methods for controlling the amount of force generated by solenoid-type magnetic structures using direct flux control.

Solenoid-type magnetic structures have been embodied in various devices, such as magnetorheological fluid dampers, control valves, fuel injectors and the like. As shown in FIG. 1, a typical solenoid-type magnetic structure, generally designated 10, may include two cores 12, 14 separated by a small air gap 16. A coil 18 may be wound onto one of the cores 14 such that, as an electric current 20 flows through the coil 18, a magnetic flux 22 is generated in the gap 16.

The resulting force generated by the magnetic structure 10 may be a function of the density of the magnetic flux 22 within the gap 16. For example, the force generated by a linear motion actuator (not shown) may be proportional to the square of the flux density in the gap 16. In magnetorheological devices, the force may be a linear function of the flux density in the gap. Therefore, the amount of force generated by a solenoid-type magnetic structure may be controlled by controlling the current 20 passing through the coil 18.

Referring to FIG. 2, a typical feedback system 30 for controlling flux response may include a current controller 32 for controlling a magnetic structure 34 to achieve a desired force 36 in response to a current command 38. The current controller 32 may be a pulse width modulation controller or the like and may generate a coil voltage command 40 (note: the coil current is a function of the coil voltage) in response to the current command 38 and the current feedback data 42 received from the magnetic structure 34.

Ideally, the density of magnetic flux in the gap 16 will follow the coil current without time delay. However, when controlling flux response using current control, the effects of induced eddy currents and hysteresis within the structure may be significant and may delay the overall flux response. For example, induced eddy currents may require a longer time interval to decay than the coil current, thereby delaying the overall flux response of the system and negatively affecting the dynamic performance of the magnetic structure.

Accordingly, there is a need for an improved system and method for controlling the flux response of magnetic structures.

### SUMMARY

In one aspect, a method for controlling a magnetic structure includes the steps of determining a flux associated with the magnetic structure and generating a control signal based, at least in part, upon the determined flux.

In another aspect, a method for controlling a flux response of a magnetic structure includes the steps of providing the magnetic structure with a coil, passing a current through the coil to generate the flux response, monitoring the flux response and adjusting the current passing through the coil based, at least in part, upon the monitored flux response.

In another aspect, a flux control system includes a magnetic structure including a coil adapted to generate a flux response in response to an electric current passing therethrough, a flux controller adapted to generate a flux command based, at least in part, upon the flux response and a current controller in communication with the magnetic structure and the flux controller, the current controller being adapted to control the electric current based, at least in part, upon the flux command.

Other aspects of the disclosed direct flux control system will become apparent from the following description, the accompanying drawings and the appended claims.

### BRIEF DESCRIPTION OF THE DRAWINGS

FIG. 1 is an elevational view of a prior art magnetic structure;

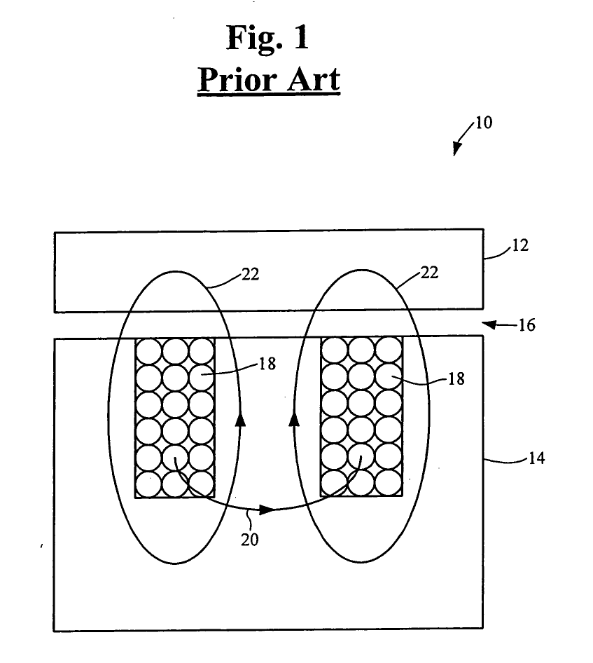

FIG. 2 is a block diagram of a prior art flux response control system;

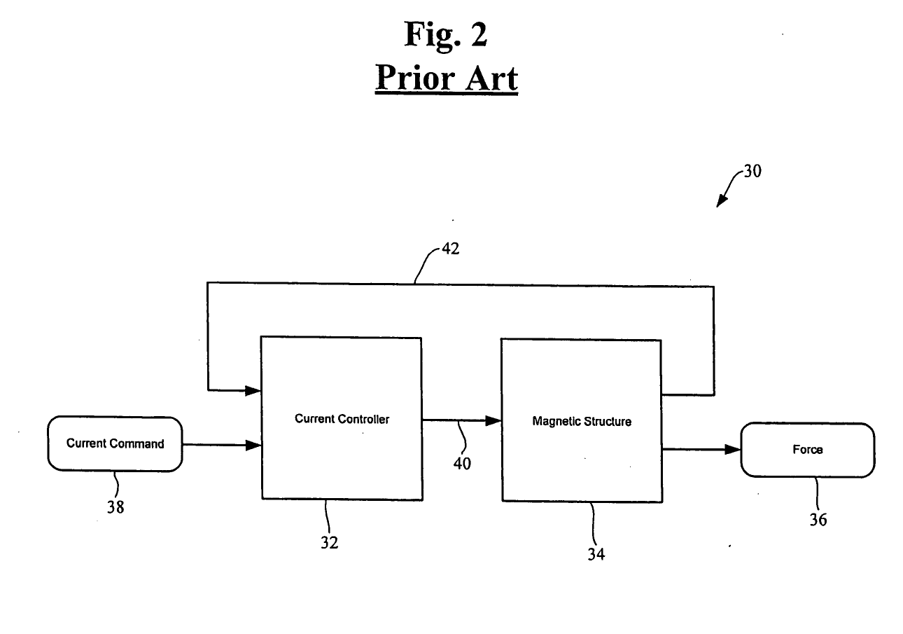

FIG. 3 is a block diagram of a flux response control system according to an aspect of the disclosed direct flux control system;

FIG. 4 is a graphical illustration of air gap flux versus time according to the control system of FIG. 3 as compared with the control system of FIG. 2;

FIG. 5 is a graphical illustration of coil current versus time according to the control system of FIG. 3 as compared with the control system of FIG. 2;

FIG. 6 is an elevational view of a magnetic structure according to an alternative aspect of the disclosed direct flux control system;

FIG. 7 is a schematic view of one aspect of a system for providing bidirectional current drive in the flux response control system of FIG. 3;

FIG. 8 is a schematic view of a second aspect of a system for providing bidirectional current drive in the flux response control system of FIG. 3; and

FIG. 9 is a schematic view of one aspect of a system for providing unidirectional current drive in the flux response control system of FIG. 3.

### DETAILED DESCRIPTION

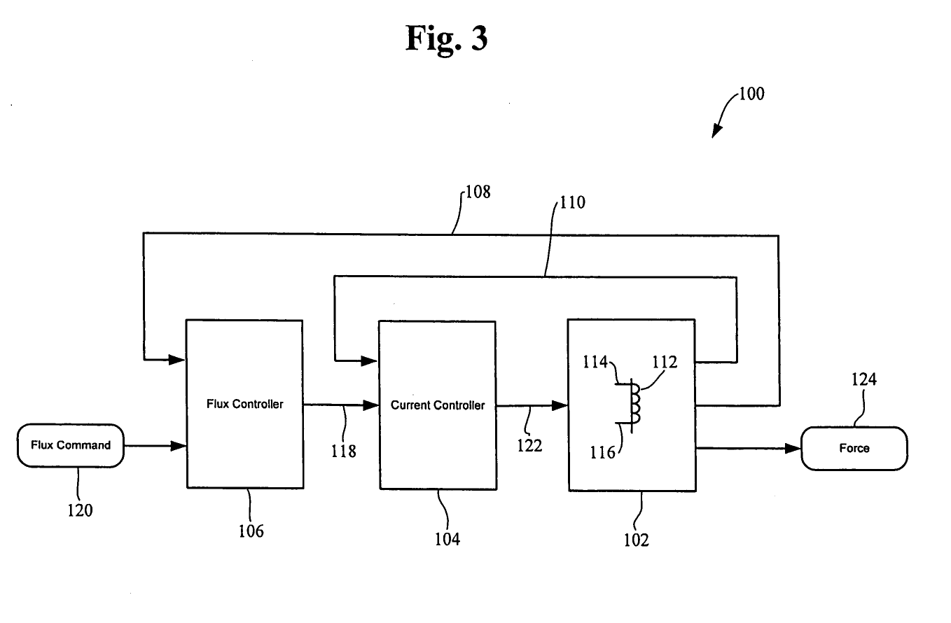

As shown in FIG. 3, an improved system for controlling flux response, generally designated 100, may include a controllable magnetic structure 102, a current controller 104 and a flux controller 106. A flux feedback loop 108 may be provided to communicate flux data from the magnetic structure 102 to the flux controller 106. An electric current feedback loop 110 may be provided to communicate electric current data from the magnetic structure 102 to the current controller 104.

The flux controller 106 may be any device or processor capable of generating a command in response to input data. For example, the flux controller 106 may be a pulse width modulation-type controller, a PID controller or the like. Furthermore, those skilled in the art will appreciate that the flux controller 106 and the current controller 104 may be separate control units or, alternatively, may be associated with a single controller and/or processing unit.

In one aspect, the controllable magnetic structure 102 may include a coil 112 adapted to generate a magnetic field when an electric current passes therethrough. For example, the controllable magnetic structure 102 may be a solenoid-type magnetic structures, such as a magnetorheological fluid damper, a control valve, a fuel injector (e.g., a diesel injector) or the like, and may include a solid core. The coil 112 may be a bidirectional coil and may include two ungrounded terminals 114, 116 such that current may flow in two directions through the coil 112. Alternatively, the coil 112 may be a unidirectional coil and may include one grounded terminal and one ungrounded terminal such that current may flow in only one direction through the coil 112.

The flux controller 106 may be adapted to generate a command 118 (e.g., a current command) in response to an input flux command 120 and the flux data provided by the flux feedback loop 108. In turn, the current controller 104 may be adapted to generate a command 122 (e.g., a voltage) in response to the command 118 and the current data provided by the current feedback loop 110, which may induce a current in the coil 112. Therefore, the magnetic structure 102 may generate a force 124 proportional to the input flux command 120. Systems for generating and controlling the current in the coil 112 are described in greater detail herein.

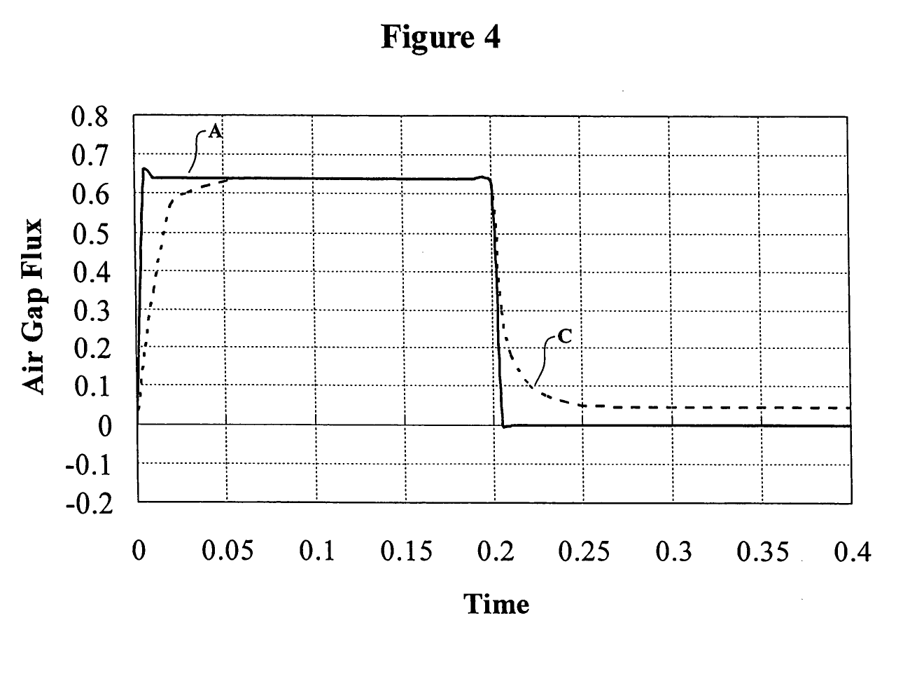

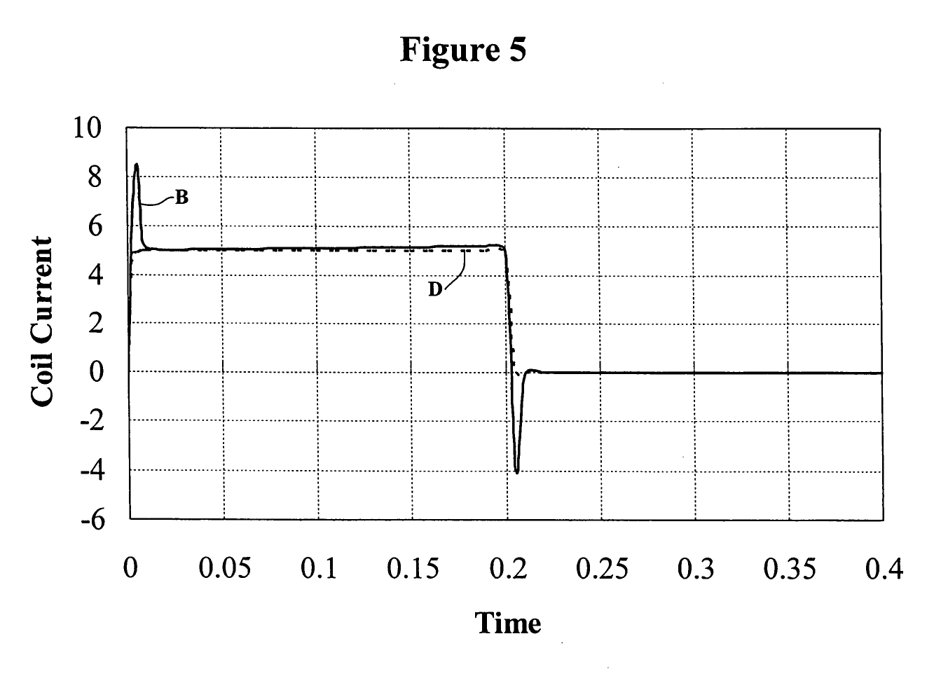

For example, referring to FIGS. 4 and 5, a magnetorheological fluid damper was configured with the flux control system 100 described above. The input flux command 120 was changed from 0 Wb to 0.65 Wb at time t=0 seconds and at time t=0.2 seconds the input flux command 120 was changed from 0.65 Wb to 0 Wb. The resulting air gap flux versus time is plotted as a solid line A in FIG. 4 and the resulting electric current within the coil 112 is shown as a solid line B in FIG. 5. For comparison, the same commands were repeated using current control (i.e., no direct flux control) and the results are shown by a broken line C in FIG. 4 and a broken line D in FIG. 5. It is clear from C, to those skilled in the art, that without flux control the flux does not return to zero due to the magnetic hysteresis of the core material.

Thus, those skilled in the art will appreciate that by controlling the flux directly, as described above, the effects of induced eddy currents and hysteresis within the magnetic structure may have little or no influence on the flux response, thereby providing a more robust system having a magnetic flux profile that closely follows the input flux command with little or no time delay.

The electric current data of the current feedback loop 110 may be obtained using any available means, including an ammeter adapted to directly measure the current in the magnetic structure (e.g., current passing through the coil 112) and communicate the current data to the current controller 104 by way of the current feedback loop 110. Likewise, the flux data of the flux feedback loop 108 may be obtained using any available means and may be measured or estimated.

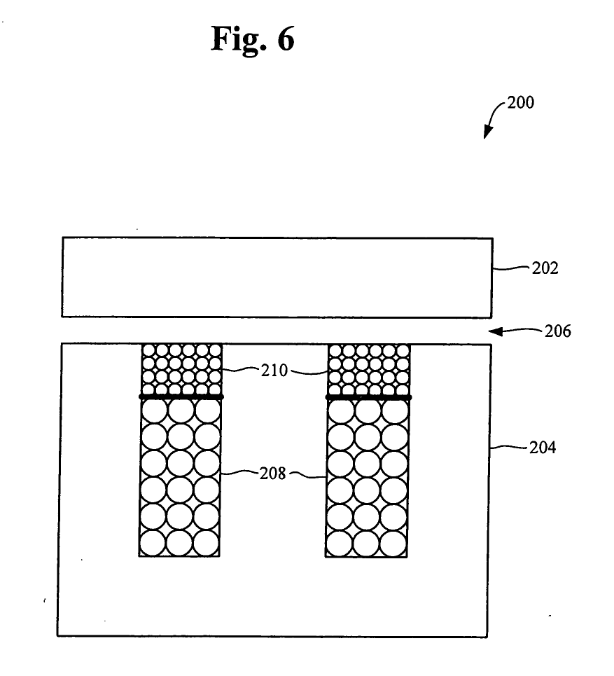

Referring to FIG. 6, an alternative aspect of a magnetic structure, generally designated 200, may include two cores 202, 204 separated by a small air gap 206. A main coil 208 may be wound onto one of the cores 204 and a separate search coil 210 may be wound adjacent to, or around, the main coil 208 and as close to the air gap 206 as possible so as to accurately measure the total air gap flux. As a controlled electric current flows through the main coil 208, a magnetic flux may be generated in the gap 206.

The magnetic flux in the air gap 206 may generate a voltage V_{SC} in the search coil 210 as follows:

$${V}_{SC} = N \frac{d ϕ}{d t} \qquad \text{(Eq. 1)}$$

wherein N is the number of turns of the search coil 210, φ is the magnetic flux in the air gap 206 and t is time. Therefore, the magnetic flux φ in the air gap 206 may be determined through integration as follows:

$$ϕ = \frac{1}{N} \int {V}_{SC} d t \qquad \text{(Eq. 2)}$$

Thus, in one aspect, a search coil 210 may be used to provide a true measurement of the magnetic flux in the air gap 206.

In another aspect, the magnetic flux in the air gap 206 may be related to the voltage V_{MC} of the main coil 208 as follows:

$${V}_{MC} = {Ri}_{coil} + N \frac{d ϕ}{d t} \qquad \text{(Eq. 3)}$$

wherein R is the resistance of the main coil 208 and associated wiring, i_{coil} is the current in the main coil 208, N is the number of turns of the main coil 210, φ is the magnetic flux in the air gap 206 and t is time. Therefore, the magnetic flux φ in the air gap 206 may be determined through integration as follows:

$$ϕ = \frac{1}{N} \int ( {V}_{MC} - {Ri}_{coil} ) d t \qquad \text{(Eq. 4)}$$

Thus, a true measurement of the magnetic flux in the air gap 206 may be obtained without the need for an additional search coil 210.

In another aspect, the magnetic flux in the air gap 206 may be estimated using a mathematical model of the coil dynamics to determine estimated values of the eddy currents and determining magnetic flux based upon measurements of the coil current combined with the estimated eddy current values.

Accordingly, by feeding back flux data to a controller capable of controlling the coil current, whether the flux feedback data is measured or estimated, the lag times associated with eddy currents and hysteresis may be overcome.

As discussed above, the coil 112 (FIG. 3) of the magnetic structure 102 of the disclosed flux control system 100 may be associated with a bidirectional system that may allow current flow in two directions through the coil (e.g., both positive and negative current flow), as shown, for example, by solid line B in FIG. 5. Alternatively, the coil 112 may be associated with a unidirectional system that may only allow current flow in one direction. In this case, flux control may be limited in its capabilities and benefits.

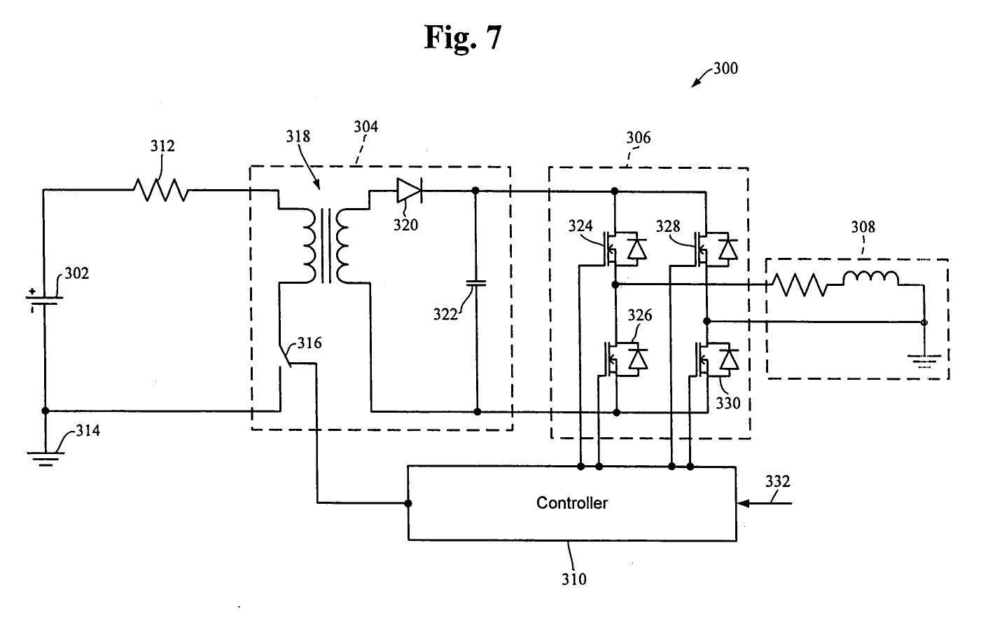

As shown in FIG. 7, one aspect of a system for providing bidirectional current drive, generally designated 300, may include a power source 302, a fly back converter 304, an H-bridge inverter 306, a grounded coil 308 and a controller 310. The system 300 may have a resistance 312.

The power source 302 may be a battery or the like and may be connected to ground 314 (e.g., a vehicle chassis). The fly back converter 304 may include a switch 316, a transformer 318, a diode 320 and a capacitor 322. The switch 316 may be in communication with the controller 310 such that the controller may open and close the switch as required. The fly back converter 304 may electrically isolate the power source 302 from the H-bridge 306 and may step-up the voltage supplied by the power source 302. For example, the fly back converter 304 may generally double the voltage supplied by the power source 302.

The H-bridge 306 may include four power switches 324, 326,328, 330, each of which may be connected to the controller 310. The power switches 324, 326, 328, 330 may be any available power switches, such as MOSFET power switches or the like.

In response to an input signal 332 (e.g., command 118 of FIG. 3), the controller 310 may open or close the switch 316 as necessary and may actuate power switches 324, 330 to achieve current flow through the grounded coil 308 in a first direction. When opposite current flow through the coil 308 is desired, the controller 310 may deactivate power switches 324, 330 and actuate power switches 326, 328.

Thus, system 300 may provide an increased voltage and a bidirectional current through a grounded coil 308.

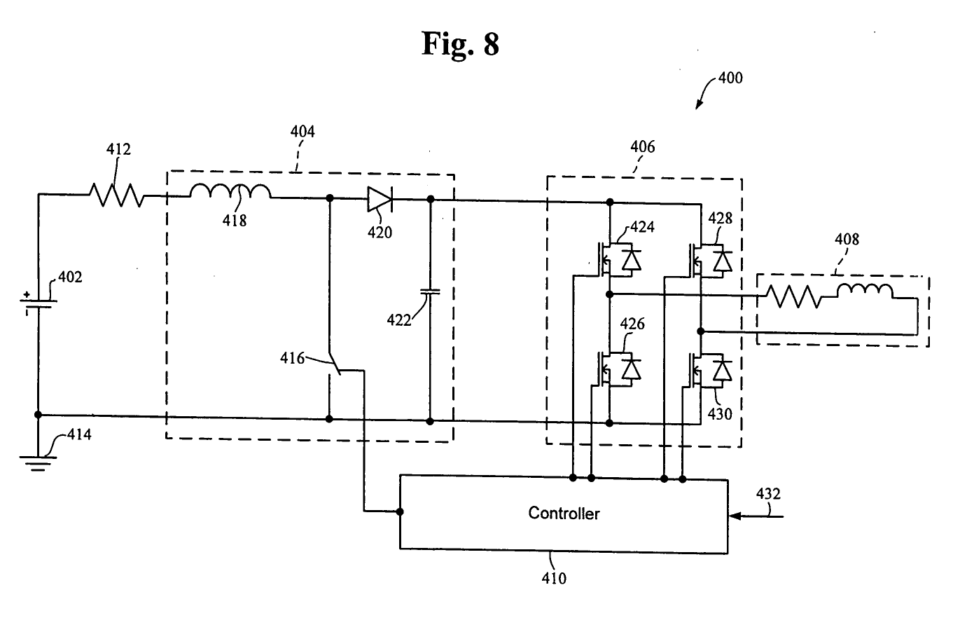

As shown in FIG. 8, an alternative system for providing bidirectional current drive, generally designated 400, may include a power source 402, a boost converter 404, an H-bridge inverter 406, an ungrounded coil 408 and a controller 410. The system 400 may have a resistance 412.

The boost converter 404 may include a switch 416, an inductor 418, a diode 420 and a capacitor 422. The switch 416 may be in communication with the controller 410 such that the controller may open and close the switch as required. The boost converter 404 may step-up the voltage supplied by the power source 402 to the H-bridge 406. For example, the boost converter 404 may generally double the voltage supplied by the power source 402.

The H-bridge 406 may include four power switches 424, 426, 428, 430, each of which may be connected to the controller 410. In response to an input signal 432 (e.g., command 118 of FIG. 3), the controller 410 may open or close the switch 416 as necessary and may actuate power switches 424, 430 to achieve current flow through the ungrounded coil 408 in a first direction. When opposite current flow through the coil 408 is desired, the controller 410 may deactivate power switches 424, 430 and actuate power switches 426, 428.

Thus, system 400 may provide an increased voltage and a bidirectional current through an ungrounded coil 408.

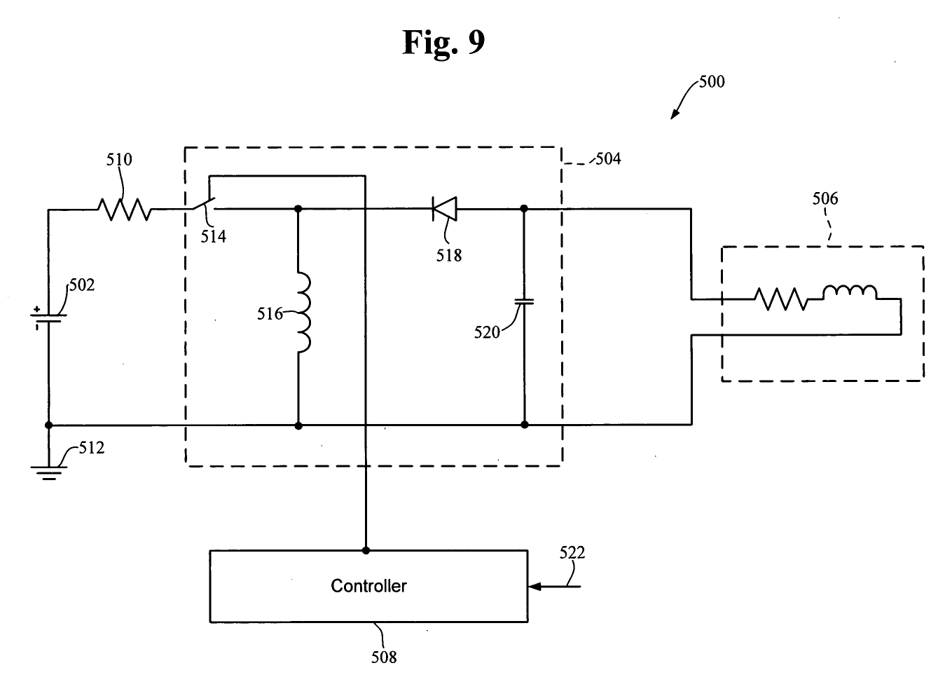

As shown in FIG. 9, one aspect of a system for providing unidirectional current drive, generally designated 500, may include a power source 502, a buck-boost converter 504, a ungrounded coil 506 and a controller 508. The system 500 may have a resistance 510. The power source 502 may be a battery or the like and may be connected to ground 512 (e.g., a vehicle chassis).

The buck-boost converter 504 may include a switch 514, an inductor 516, a diode 518 and a capacitor 520. The switch 514 may be in communication with the controller 508 such that the controller may open and close the switch as required. Therefore, the buck-boost converter 504 may step-up the voltage supplied by the power source 502. For example, the buck-boost converter 504 may generally double the voltage supplied by the power source 502.

Thus, in response to an input signal 522 (e.g., command 118 of FIG. 3), the controller 508 may open or close the switch 514 until the desired current flows through the coil 506, thereby providing an increased voltage and a unidirectional current through the grounded coil 506.

At this point, those skilled in the art will appreciate that both unidirectional and bidirectional currents may be used to generate magnetic flux in the flux control systems described herein. They will also appreciate that unidirectional currents will only allow partial flux control. Full flux control may require bidirectional control of the current. Furthermore, those skilled in the art will appreciate that various systems and techniques may be used with the flux control systems described herein to achieve unidirectional and bidirectional current flow.

Although various aspects of the disclosed direct flux control system have been shown and described, modifications may occur to those skilled in the art upon reading the specification. The present application includes such modifications and is limited only by the scope of the claims.

What is claimed is:

1. A method for controlling a magnetic structure comprising the steps of:
determining a flux associated with said magnetic structure; and
generating a control signal based, at least in part, upon said determined flux.

2. The method of claim 1 wherein said magnetic structure is a solenoid-type magnetic structure.

3. The method of claim 2 wherein said solenoid-type magnetic structure includes at least one solid core.

4. The method of claim 1 wherein said determining step includes estimating said flux.

5. The method of claim 1 wherein said determining step includes measuring said flux.

6. The method of claim 5 wherein said flux is measured using a search coil.

7. The method of claim 1 further comprising the step of generating a flux response based, at least in part, upon said control signal.

8. The method of claim 1 wherein said magnetic structure includes a coil having a controllable current passing therethrough and said controllable current is controlled based, at least in part, upon said control signal.

9. The method of claim 8 wherein said determining step includes measuring said flux based, at least in part, upon a voltage of said controllable coil.

10. The method of claim 8 wherein said controllable current is adapted to pass through said coil bidirectionally.

11. The method of claim 8 wherein said controllable current is adapted to pass through said coil unidirectionally.

12. A method for controlling a flux response of a magnetic structure comprising the steps of:
providing said magnetic structure with a coil;
passing a current through said coil to generate said flux response;
monitoring said flux response; and
adjusting said current passing through said coil based, at least in part, upon said monitored flux response.

13. The method of claim 12 wherein said magnetic structure is a solenoid-type magnetic structure.

14. The method of claim 13 wherein said solenoid-type magnetic structure includes at least one solid core.

15. The method of claim 12 wherein said monitoring step includes estimating a flux associated with said magnetic structure.

16. The method of claim 12 wherein said monitoring step includes measuring a flux associated with said magnetic structure.

17. The method of claim 16 wherein said flux is measured using a search coil.

18. The method of claim 12 wherein said current is adapted to pass through said coil bidirectionally.

19. The method of claim 12 further comprising repeating said passing monitoring and adjusting steps a achieve a desired flux response.

20. A flux control system comprising:
a magnetic structure including a coil adapted to generate a flux response in response to an electric current passing therethrough;
a flux controller adapted to generate a flux command based, at least in part, upon said flux response; and
a current controller in communication with said magnetic structure and said flux controller, said current controller being adapted to control said electric current based, at least in part, upon said flux command.

21. The flux control system of claim 20 wherein said flux controller and said current controller are associated with a single processing unit.
